(19) United States
(12) Patent Application Publication
(10) Pub. No.: US 2008/0282123 A1
(43) Pub. Date: Nov. 13, 2008

(54) System and Method of Multi-Frequency Integrated Circuit Testing

(76) Inventors: Charles L. Meissner, Austin, TX (US); Pedro Martin-de-Nicolas, Austin, TX (US); Gerard M. Salem, Essex Junction, VT (US)

Correspondence Address: IBM CORPORATION (VE);C/O VOLEL EMILE, P. O. BOX 162485, AUSTIN, TX, 78716, US

(21) Appl. No.: 11/746,715

(22) Filed: May 10, 2007

(51) Int. Cl. G01R 31/317

(52) U.S. Cl. 714/734

(57) ABSTRACT

A system and method of multi-frequency integrated circuit testing with a method for testing a clocked logic type integrated circuit including creating exerciser code on the integrated circuit when the integrated circuit is operating at a first frequency, switching the integrated circuit to operating at a second frequency greater than the first frequency, and running the exerciser code on the integrated circuit when the integrated circuit is operating at the second frequency.

### TECHNICAL FIELD

The technical field of this disclosure is integrated circuit design and development, particularly, a system and method of multi-frequency integrated circuit testing.

### BACKGROUND OF THE INVENTION

The design and fabrication of clocked logic type integrated circuits, such as microprocessors, requires testing to verify that the integrated circuits will operate over anticipated conditions. Test code is run on the integrated circuit to check performance of the integrated circuit during operation.

The test code can be divided into generation code and exerciser code. The exerciser code is generated by the integrated circuit itself using the generation code, and then run on the integrated circuit. Although the testing is designed to identify failures when the exerciser code is running, the test code can fail when the exerciser code is being generated by the generation code or when the exerciser code is running to test the integrated circuit. Failure when running the exerciser code is usually easy to debug, because the exerciser code generally small and is designed to be easy to debug. Unfortunately, debugging failures that occur when running the generation code is much more difficult, because the generation code is large and complex, and is not designed to be debugged.

Presently, the practice is to expect failures to occur when running the generation code and to perform difficult, costly, time consuming debugging when the failures do occur. Even this is not a complete solution, however. Problems with the generation code can prevent generation of exerciser code able to isolate specific errors arising from specific functions, e.g., errors arising from floating point operations. The testing cannot be completed and failures may not be discovered until the integrated circuit is in production or in the field. This results in expensive recalls and repairs. Although reducing the frequency of the integrated circuit would be expected to reduce failures when generating exerciser code, a reduced frequency would not adequately stress test the integrated circuit.

It would be desirable to have a system and method of multi-frequency integrated circuit testing that would overcome the above disadvantages.

### SUMMARY OF THE INVENTION

The system and method of multi-frequency integrated circuit testing of the present invention improves testing of clocked logic type integrated circuits. Generation code, which creates exerciser code, runs on the integrated circuit at a lower frequency than the exerciser code, which tests the integrated circuit. Running the generator code at a lower frequency reduces the chance that the testing will fail while the generation code is running. This allows efficient testing and reduces unproductive debugging of the generation code, improving integrated circuit quality and reducing time to market.

One aspect of the present invention provides a method for testing a clocked logic type integrated circuit including creating exerciser code on the integrated circuit when the integrated circuit is operating at a first frequency; switching the integrated circuit to operating at a second frequency greater than the first frequency; and running the exerciser code on the integrated circuit when the integrated circuit is operating at the second frequency.

Another aspect of the present invention provides a computer program product in a computer usable medium for testing a clocked logic type integrated circuit, the computer program product including computer program code for creating exerciser code on the integrated circuit when the integrated circuit is operating at a first frequency; computer program code for switching the integrated circuit to operating at a second frequency greater than the first frequency; and computer program code for running the exerciser code on the integrated circuit when the integrated circuit is operating at the second frequency.

Another aspect of the present invention provides an information handling system including a processor; and a memory coupled to said processor to store instructions executable by a digital processing apparatus to perform operations to provide testing of a clocked logic type integrated circuit. The operations include creating exerciser code on the integrated circuit when the integrated circuit is operating at a first frequency; switching the integrated circuit to operating at a second frequency greater than the first frequency; and running the exerciser code on the integrated circuit when the integrated circuit is operating at the second frequency.

The foregoing and other features and advantages of the invention will become further apparent from the following detailed description of the presently preferred embodiments, read in conjunction with the accompanying drawings. The detailed description and drawings are merely illustrative of the invention, rather than limiting the scope of the invention being defined by the appended claims and equivalents thereof.

### BRIEF DESCRIPTION OF THE DRAWINGS

FIG. 1 is a block diagram of a multi-frequency integrated circuit for use in multi-frequency integrated circuit testing in accordance with the present invention;

FIG. 2 is a flow chart of a method for multi-frequency integrated circuit testing in accordance with the present invention; and

FIG. 3 is a block diagram of an information handling system for implementing multi-frequency integrated circuit testing in accordance with the present invention.

### DETAILED DESCRIPTION OF PREFERRED EMBODIMENTS

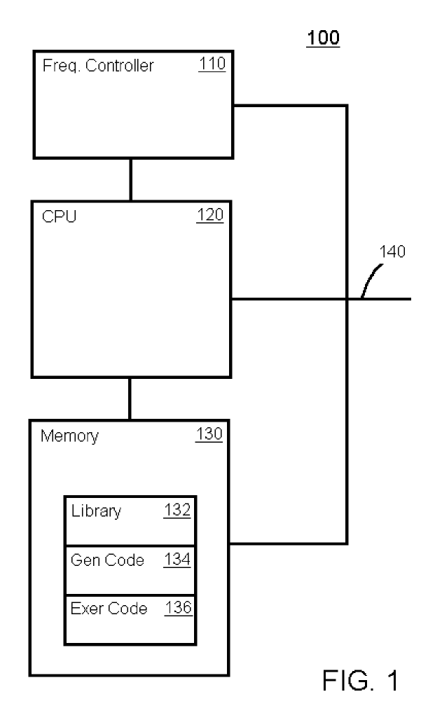

FIG. 1 is a block diagram of a multi-frequency integrated circuit for use in multi-frequency integrated circuit testing in accordance with the present invention. In this example, the integrated circuit 100 includes a frequency controller 110, a central processing unit (CPU) 120, and a memory 130, which can store a library 132, generation code 134, and exerciser code 136 during testing. The integrated circuit 100 can exchange data with other devices and/or systems over integrated circuit bus 140. The integrated circuit 100 can be any integrated circuit capable of operating at multiple frequencies. In one embodiment, the frequency switching is under the control of the integrated circuit, such as being under control of the central processing unit 120 of the integrated circuit. Testing is faster and/or more effective when the integrated circuit can quickly change from one frequency to another, so more test cases can be run.

The frequency controller 110 controls the frequency at which the integrated circuit 100 operates. In one embodiment, the frequency controller 110 operates the integrated circuit 100 at a nominal operating frequency and at other operating frequencies that are fractions of the nominal operating frequency, such as one half, one quarter, and/or one sixty-fourth of the nominal operating frequency. Frequency control is commonly available in integrated circuits, such as processors, for power management, also known as power scaling or power tuning. The frequency can be changed quickly, on-the-fly, to reduce power use to the minimum needed for a particular mode of operation. The frequency controller 110 can change the frequency in response to a write to a special register in the integrated circuit 100 or a write to a memory-mapped I/O device on or off the integrated circuit.

The central processing unit 120 can be any central processing unit to be tested. The central processing unit 120 can include internal components, such as caches, registers, arithmetic logic units, and the like. The central processing unit 120 is responsive to the frequency controller 110 to operate at the nominal operating frequency or another operating frequency, such as a fraction of the nominal operating frequency. The central processing unit 120 runs the generation code 134 and exerciser code 136. In one embodiment, the generation code 134 and exerciser code 136 run on a Test nano Kernel running on the central processing unit 120. Such a Test nano Kernel is described in U.S. Pat. No. 6,357,020, to Bohizic, et al., entitled Method and System for Low Level Testing of Central Electronics Complex Hardware using Test nano Kernel, incorporated in its entirety by reference herein. The Test nano Kernel is a low level hardware stress tool that requires approximately 500 K of memory or cache to operate and provides services in addition to the major subset of standard UNIX functions. The Test nano Kernel and the exerciser code 136 stage stress and/or validity tests on the integrated circuit 100. The central processing unit 120 exchanges data and instructions with the memory 130. Those skilled in the art will appreciate that the frequency controller 110 can be inside the central processing unit 120 or outside the central processing unit 120.

The memory 130 stores the library 132, generation code 134, and exerciser code 136. The library 132, generation code 134, and exerciser code 136 can be loaded into the memory 130 from outside the integrated circuit 100 through the integrated circuit bus 140. The generation code 134 can access code and instructions stored in the library 132 to assemble the exerciser code 136. The generation code 134 and exerciser code 136 run on the central processing unit 120. The memory 130 can also store the results of running the exerciser code 136.

Those skilled in the art will appreciate that the integrated circuit 100 of FIG. 1 is a functional description of the integrated circuit and many variations are possible. The frequency controller 110, central processing unit 120, and memory 130 can be on a single chip or on multiple chips. Code and instructions can be stored in the memory 130 within the integrated circuit 100 or at other locations outside the integrated circuit 100 and loaded into the integrated circuit 100. In one embodiment, the integrated circuit 100 is a microprocessor, such as the PowerPC 970MP manufactured by the International Business Machines of Armonk, N.Y. The integrated circuit 100 can be a single or multi processor integrated circuit.

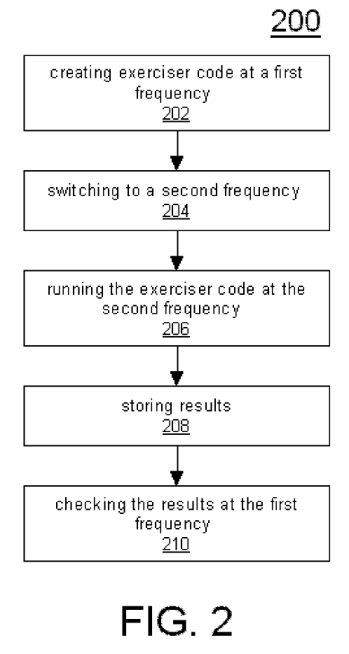

FIG. 2 is a flow chart of a method for multi-frequency integrated circuit testing in accordance with the present invention. The method 200 for testing a clocked logic type integrated circuit includes creating exerciser code at a first frequency 202, switching to a second frequency 204, and running the exerciser code at the second frequency 206. The first frequency is less than the second frequency to reduce stress on the integrated circuit and reduce the likelihood of failures when creating the exerciser code. The first frequency and the second frequency can be any desired testing frequencies, with the first frequency being less than the second frequency. In one embodiment, the second frequency is the nominal operating frequency. In one embodiment, the first frequency is a fraction of the second frequency, such as about one-half of the second frequency. Those skilled in the art will appreciate that the first frequency and the second frequency can be any frequencies at which the integrated circuit can be clocked. The method 200 can end after running the exerciser code at the second frequency 206 or can return to creating exerciser code at a first frequency 202 for additional testing.

The results of running the exerciser code can be stored and checked. The method 200 can also include storing results 208 such as storing results of the running the exerciser code, and checking the results at the first frequency 210 such as checking the results when the integrated circuit is operating at the first frequency. Checking the results at the first frequency 210 rather than the higher second frequency reduces the likelihood of failures during the checking. The results can be stored in the memory 130 and checked in the central processing unit 120. In another embodiment, the results can be stored in the memory 130 and checked outside the integrated circuit.

The exerciser code can be run at more than one frequency to see if the results differ at different frequencies. In one embodiment, the method 200 can include running the exerciser code on the integrated circuit when the integrated circuit is operating at a third frequency different than the second frequency. The results of running the exerciser code on the integrated circuit when the integrated circuit is operating at the second frequency can be compared to the results of the running the exerciser code on the integrated circuit when the integrated circuit is operating at the third frequency to see if the results differ. The third frequency can be any desired testing frequency, such as the nominal operating frequency or a frequency less than or greater than the second frequency. In another embodiment, the exerciser code can be run more than once at one frequency to check the repeatability and/or variation of the results.

Creating exerciser code at a first frequency 202 includes creating exerciser code on the integrated circuit when the integrated circuit is operating at a first frequency. In one embodiment, the creating includes selecting test instructions from an instruction table and assembling the test instructions into the exerciser code. The test instructions in the instruction table can be stored in the library of the memory of the integrated circuit. In one embodiment, the exerciser code is randomly generated from the instructions stored in the library. In one embodiment, the exerciser code is relatively short, such as forty instructions.

Switching to a second frequency 204 includes switching the integrated circuit to operating at a second frequency greater than the first frequency. The second frequency can be any frequency greater than the first frequency that is supported by the integrated circuit. In one embodiment, the second frequency is the nominal operating frequency for the integrated circuit. The frequency switching can be performed by the frequency controller in response to a write to a special register in the integrated circuit or a write to a memory-mapped I/O device on or off the integrated circuit. In one embodiment, the frequency switching is under the control of the integrated circuit, such as being under control of the central processor unit of the integrated circuit.

Running the exerciser code at the second frequency 206 includes running the exerciser code on the integrated circuit when the integrated circuit is operating at the second frequency. The second frequency is higher than the first frequency to provide more stress on the integrated circuit and better test integrated circuit operation.

The running of code on the integrated circuit can include running the code on a Test nano Kernel, which can run as an operating system on the integrated circuit. The code for creating exerciser code, the exerciser code, and/or the code for checking the results of running the exerciser code can run on the Test nano Kernel. The Test nano Kernel can run simple Unix commands and can be based on the Minix Operating System with modifications as desired to support multi-processors, context execution, vector ownership, 32 bit or 64 bit execution, interrupt vector control, random code generators, random number generators, and the like. The exerciser code can run simple instruction streams. The code for creating exerciser code (generation code) can generate pseudo random instruction streams in the exerciser code using the random code generators of the Test nano Kernel.

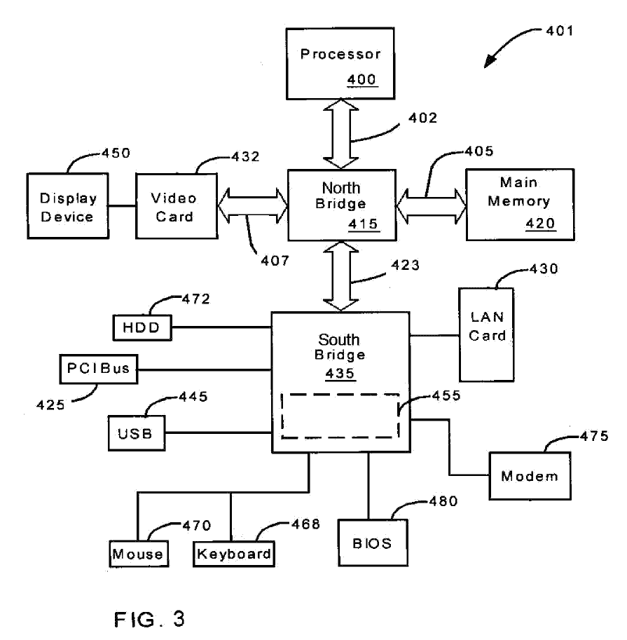

FIG. 3 is a block diagram of an information handling system for implementing multi-frequency integrated circuit testing in accordance with the present invention. The information handling system 401 is a simplified example of a computer system capable of performing the operations described herein. The information handling system 401 includes processor 400, which is coupled to northbridge 415 with a processor bus 402. The processor 400 can also use internal and/or external level two (L2) cache memory. The northbridge 415 is coupled to main memory 420 with a memory bus 405 and is coupled to video card 432 with an AGP bus 407. The video card 432 is operably connected to a display device 450, such as a liquid crystal display (LCD), a cathode ray tube (CRT) display, a projection display, or the like. Those skilled in the art will appreciate that the video card 432 can be attached to other types of busses, such as a PCI or PCI Express bus, as desired for a particular application. The northbridge 415, also known as a memory controller hub, manages communications between the processor 400, the main memory 420, the video card 432, and southbridge 435. The northbridge 415 is coupled to the southbridge 435 with high speed chip-to-chip interconnect bus 423.

The southbridge 435, also known as an I/O controller hub, manages communications between input/output devices and the northbridge 415. The southbridge 435 can include power management functionality 455 and other functional elements not shown, such as a real-time clock (RTC), DMA control, interrupt support, and system management bus support. Input/output (I/O) devices and peripheral devices can be attached to the southbridge 435 directly or through various interfaces. Exemplary I/O devices and interfaces include fixed disk (HDD) 472, PCI bus 425, universal serial bus (USB) 445, mouse 470, keyboard 468, BIOS 480, modem 475, and LAN card 430. The BIOS 480 is coupled to the southbridge 435, and incorporates the necessary processor executable code for a variety of low-level system functions and system boot functions. The BIOS 480 can be stored in any computer readable medium, including magnetic storage media, optical storage media, flash memory, random access memory, read only memory, and communications media conveying signals encoding the instructions (e.g., signals from a network). Those skilled in that art will appreciate that various I/O devices and interfaces can be used as desired for a particular application.

While the computer system described in FIG. 3 is capable of executing the invention described herein, this computer system is simply one example of a computer system. Another such example is routing of communication controller commands between integrated circuits in a multi-processor or multi-node configuration over a system interconnection bus. Those skilled in the art will appreciate that many other computer system designs are capable of performing the invention described herein.

One of the preferred implementations of the invention is an application, namely, a set of instructions (program code) in a code module which may, for example, be resident in the random access memory of the computer. Until required by the computer, the set of instructions may be stored in another computer memory, for example, on a hard disk drive, or in removable storage such as an optical disk (for eventual use in a CD ROM) or floppy disk (for eventual use in a floppy disk drive), or downloaded via the Internet or other computer network. Thus, the present invention may be implemented as a computer program stored on a computer readable medium and executable by a digital processing apparatus to perform operations to provide testing of a clocked logic type integrated circuit. In addition, although the various methods described are conveniently implemented in a general purpose computer selectively activated or reconfigured by software, one of ordinary skill in the art would also recognize that such methods may be carried out in hardware, in firmware, or in more specialized apparatus constructed to perform the required method steps.

While the embodiments of the invention disclosed herein are presently considered to be preferred, various changes and modifications can be made without departing from the spirit and scope of the invention. The scope of the invention is indicated in the appended claims, and all changes that come within the meaning and range of equivalents are intended to be embraced therein.

We claim:

1. A method for testing a clocked logic type integrated circuit comprising:
creating exerciser code on the integrated circuit when the integrated circuit is operating at a first frequency;
switching the integrated circuit to operating at a second frequency greater than the first frequency; and
running the exerciser code on the integrated circuit when the integrated circuit is operating at the second frequency.

2. The method of claim 1 further comprising:
storing results of the running the exerciser code; and
checking the results when the integrated circuit is operating at the first frequency.

3. The method of claim 1 further comprising running the exerciser code on the integrated circuit when the integrated circuit is operating at a third frequency different than the second frequency.

4. The method of claim 3 further comprising comparing results of the running the exerciser code on the integrated circuit when the integrated circuit is operating at the second frequency to results of the running the exerciser code on the integrated circuit when the integrated circuit is operating at the third frequency.

5. The method of claim 1 wherein the creating comprises:
selecting test instructions from an instruction table; and
assembling the test instructions into the exerciser code.

6. The method of claim 1 wherein the integrated circuit has a central processing unit, and the switching is under control of the central processing unit.

7. The method of claim 1 wherein the second frequency is nominal operating frequency of the integrated circuit.

8. A computer program product in a computer usable medium for testing a clocked logic type integrated circuit, the computer program product comprising:
computer program code for creating exerciser code on the integrated circuit when the integrated circuit is operating at a first frequency;
computer program code for switching the integrated circuit to operating at a second frequency greater than the first frequency; and
computer program code for running the exerciser code on the integrated circuit when the integrated circuit is operating at the second frequency.

9. The computer program product of claim 8 further comprising:
computer program code for storing results of the running the exerciser code; and
computer program code for checking the results when the integrated circuit is operating at the first frequency.

10. The computer program product of claim 8 further comprising computer program code for running the exerciser code on the integrated circuit when the integrated circuit is operating at a third frequency different than the second frequency.

11. The computer program product of claim 10 further comprising computer program code for comparing results of the running the exerciser code on the integrated circuit when the integrated circuit is operating at the second frequency to results of the running the exerciser code on the integrated circuit when the integrated circuit is operating at the third frequency.

12. The computer program product of claim 8 wherein the computer program code for creating comprises:
computer program code for selecting test instructions from an instruction table; and
computer program code for assembling the test instructions into the exerciser code.

13. The computer program product of claim 8 wherein the integrated circuit has a central processing unit, and the computer program code for switching comprises computer program code for switching under control of the central processing unit.

14. The computer program product of claim 8 wherein the second frequency is nominal operating frequency of the integrated circuit.

15. An information handling system comprising:
a processor; and
a memory coupled to said processor to store instructions executable by a digital processing apparatus to perform operations to provide testing of a clocked logic type integrated circuit, the operations comprising:
creating exerciser code on the integrated circuit when the integrated circuit is operating at a first frequency;
switching the integrated circuit to operating at a second frequency greater than the first frequency; and
running the exerciser code on the integrated circuit when the integrated circuit is operating at the second frequency.

16. The system of claim 15, the operations further comprising:
storing results of the running the exerciser code; and
checking the results when the integrated circuit is operating at the first frequency.

17. The system of claim 15, the operations further comprising running the exerciser code on the integrated circuit when the integrated circuit is operating at a third frequency different than the second frequency.

18. The system of claim 17, the operations further comprising comparing results of the running the exerciser code on the integrated circuit when the integrated circuit is operating at the second frequency to results of the running the exerciser code on the integrated circuit when the integrated circuit is operating at the third frequency.

19. The system of claim 15 wherein the creating comprises:
selecting test instructions from an instruction table; and
assembling the test instructions into the exerciser code.

20. The system of claim 15 wherein the integrated circuit has a central processing unit, and the switching is under control of the central processing unit.
